(19) United States
(12) Patent Application Publication
(10) Pub. No.: US 2009/0113275 A1
(43) Pub. Date: Apr. 30, 2009

(54) BCH CODE WITH 256 INFORMATION BYTES AND UP TO 8 BYTES OF PARITY CHECK ELEMENTS

(75) Inventors: LEI CHEN, Santa Clara, CA (US); Yan Znong, San Jose, CA (US)

Correspondence Address: FRANK F. TIAN, 331-4A THIRD AVENUE, LONG BEACH, NJ, 07740, US

(73) Assignee: LEGEND SILICON CORP., FREMONT, CA (US)

(21) Appl. No.: 11/926,334

(22) Filed: Oct. 29, 2007

(51) Int. Cl. H03M 13/00

(52) U.S. Cl. 714/782

(57) ABSTRACT

A coding system comprises pre-multiply the message u(x) by Xn−k. Obtain the remainder b(x), i.e. the parity check digits. And combine b(x) and Xn−ku(x) to obtain the code polynomial. A decoding method comprises calculating a syndrome; finding an error-location polynomial; and computing a set of error location numbers.

### FIELD OF THE INVENTION

The present invention relates generally to coding systems. More specifically, the present invention relates to a BCH code with 256 information bytes and up to 8 bytes of parity check elements.

### BACKGROUND

Bose-Chadhuri-Hocquenghem (BCH) code is known. United States Patent Application No. 20040181735 by Xin, Weizhuang (Wayne) discloses decoding a received BCH encoded signal comprising a method or apparatus for decoding of a BCH encoded signal, which begins by determining whether the received BCH encoded signal includes error. The decoding process continues when the received BCH encoded signal includes error by determining whether the error is correctable. This may be done by determining a number of errors of the received BCH encoded signal, identifying bit locations of the received BCH encoded signal having the error; counting the number of bit locations of the received BCH encoded signal having the error, comparing the number of errors to the number of bit locations of the received BCH encoded signal having the error, when the number of bit locations of the received BCH encoded signal having the error equals the number of errors, ceasing the identifying of the bit locations of the received BCH encoded signal having the error, and correcting information contained in the bit locations of the received BCH encoded signal having the error when the identifying of the bit locations is ceased.

However, there are needs in both the design method and the encoding/decoding method for a suitable BCH coding system having a suitably long code (e.g. with 256 information bytes and up to 8 bytes of parity check elements). This is especially true for the design of a BCH code, whereby both the minimal polynomials and generator polynomial are very hard to generate. Furthermore, during the design stage of the BCH code, shortening is performed. Shortening makes the design special, also distinguishes the decoding methods with others.

### SUMMARY OF THE INVENTION

A BCH code with 256 information bytes and up to 8 bytes of parity check elements is provided.

A coding system comprises pre-multiply the message u(x) by Xn−k. Obtain the remainder b(x), i.e. the parity check digits. And combine b(x) and Xn−ku(x) to obtain the code polynomial.

A decoding method comprises calculating a syndrome; finding an error-location polynomial; and computing a set of error location numbers.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example of an encoding circuit in accordance with some embodiments of the invention.

FIG. 2 is an example of an encoding process in accordance with some embodiments of the invention.

FIG. 3 is an example of a decoding process in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to a BCH code with two hundred fifty six (256) information bytes and up to eight (8) bytes of parity check elements. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of relating to a BCH code with two hundred fifty six (256) information bytes and up to eight (8) bytes of parity check elements. In the exemplified embodiments, it is noted that the processors include Finite State Machines, which are used in the preferred embodiment. The non-processor circuits may include, but are not limited to, a radio receiver, a radio transmitter, signal drivers, clock circuits, power source circuits, and user input devices. As such, these functions may be interpreted as steps of a method with reduced memory requirements to perform a BCH code with two hundred fifty six (256) information bytes and up to eight (8) bytes of parity check elements. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

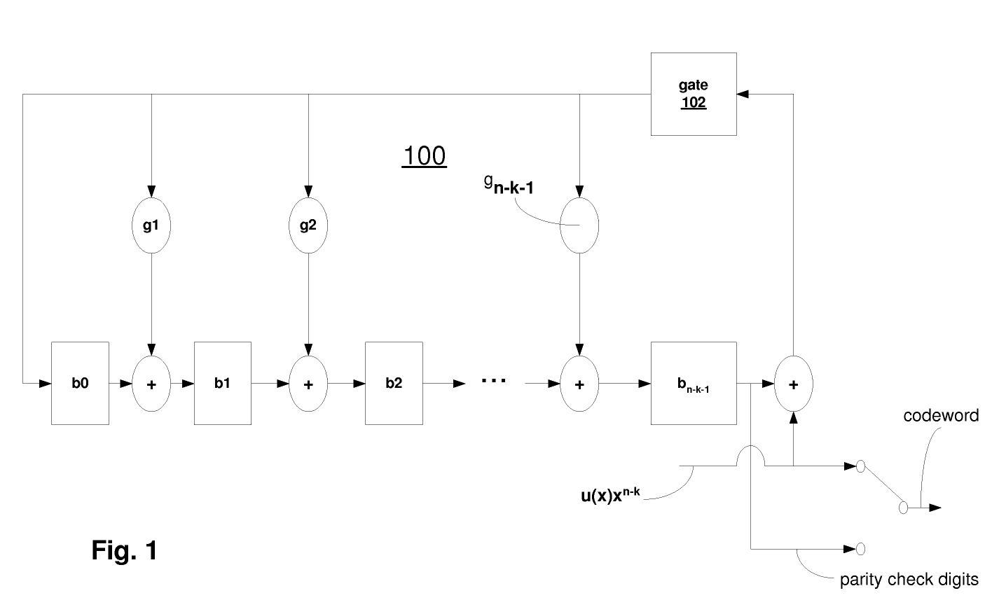

Referring to FIG. 1, a generic encoding circuit 100 is shown for an (n, k) cyclic code with generator polynomial: g(X)=1+g₁X²+ . . . +gₙ₋ₖ₋₁X^{n-k-1}+X^{n-k}. Gate 102 is turned on to process the k information digits u₀, u₁, . . . , uₖ₋₁ or in the polynomial form of u(x)=u₀+u₁X+ . . . +uₖ₋₁X^{k-1} are shifted into circuit 100 while simultaneously go into a communication channel as well. Shifting the message u(X) into circuit 100 from the front end is equivalent to pre-multiplying u(X) by X^{n-k}. As soon as the complete message has entered circuit 100, the n−k digits in the register form the reminder, i.e. the parity check digits. In turn, gate 102 is turned off to break the feedback connection. Parity check digits are shifted out and, in turn, send to channel. The codeword is formed by the n−k parity check digits b₀, b₁, . . . b₁₋ₖ₋₁, together with the k information digits.

A Bose-Chadhuri-Hocquenghem (BCH) code with 256 information bytes and up to 8 bytes of parity check elements suitable for generating by the circuit 100 of FIG. 1 is provided. For an eight bit word length processing system, information bits are equal to two thousand and forty eight bits (256*8=2048 bits). The corresponding parity bits equal to sixty four (8*8=64) bits.

Let m=12 and t=4, we got n=4095; i.e. n=2^{m}−1=2¹²−1=4095

The primitive polynomial is:

p(x)=1+X+X⁴+X⁶+X¹² Eq. 1

with n=4095, we get k=4047

We also get the generator polynomial as:

g(X)=1+X+X³+X⁵+X⁷+X¹³+X¹⁶+X¹⁷+X²¹+X²⁶+X²⁷+X²⁹+X³²+X³⁴+X³⁶+X³⁷+X⁴¹+X⁴⁴+X⁴⁸ Eq. 2

resulting in a (4095, 4047) BCH expression.

Since we need k=2048, and 4047−2048=1999, therefore, if we shorten the (4095, 4047) BCH code by 1999 bits we get a (2096, 2048) shortened BCH code.

Minimal polynomials of the BCH code for the encoder is as follows:

α: φ₁(X)=1+X+X⁴+X⁶+X¹²

α³: φ₃(X)=1+X+X³+X⁴+X⁶+X¹⁰+X¹²

α⁵: φ₅(X)=1+X+X²+X³+X⁶+X¹²

α⁷: φ₇(X)=1+X+X³+X⁵+X⁶+X¹⁰+X¹²

Because BCH code is a cyclic code, therefore given a generator polynomial g(X) of an (n, k) cyclic code, we can put the code into systematic form such as the following:

(message) information is: (u₀, u₁, . . . , uₖ₋₁), and

Code word is: (b₀, b₁, . . . , bₙ₋ₖ₋₁, u₀, u₁, . . . , uₖ₋₁).

As can be seen the right most k digits of the code word are the unaltered information digits, and the leftmost n−k digits are parity-check digits.

Let message be:

\vec{u}=(u₀,u₁, . . . , uₖ₋₁) Eq. 3

Then,

u(x)=u₀+u₁X+ . . . +uₖ₋₁X^{k-1} Eq. 4.

Multiply both sides of Eq. 4 by X^{n-k}, we got:

X^{n-k}u(X)=X^{n-k}u₀+u₁X^{n-k+1}+ . . . +uₖ₋₁Xⁿ⁻¹ Eq 5

Dividing Eq. 5 (i.e. X^{n-k}u(x)) by g(x), we can get the following expression:

X^{n-k}u(x)=a(x)g(x)+b(x) Eq. 6

Since g(x) has n−k degrees, the degree of b(x) must be n−k−1 or less, that is:

b(x)=b₀+b₁X+ . . . +bₙ₋ₖ₋₁X^{n-k-1} Eq. 7

b(x)+X^{n-k}u(x)=a(x)g(x) Eq. 8

As can be seen this polynomial is a multiple of g(x) and therefore is a code polynomial. Combining equations six and seven (Eq. 6 and Eq. 7), we get:

b(x)+X^{n-k}u(x)=b₀+b₁X+ . . . +bₙ₋ₖ₋₁X^{n-k-1}+X^{n-k}u₀+u₁X^{n-k+1}+ . . . +uₖ₋₁Xⁿ⁻¹ Eq. 9

which corresponds to the code word (b₀, b₁, . . . , bₙ₋ₖ₋₁, u₀, u₁, . . . , uₖ₋₁).

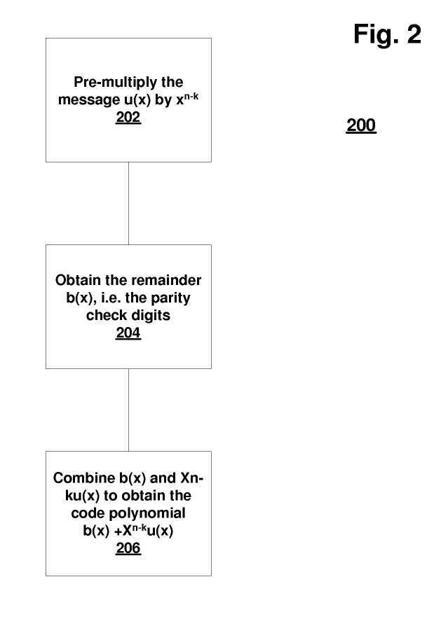

The coding can be realized as shown in FIG. 2. In summary, coding in systematic form comprises of 3 steps.
1. Pre-multiply the message u(x) by X^{n-k} (Step 202);
2. Obtain the remainder b(x), i.e. the parity check digits (Step 204); and
3. Combine b(x) and X^{n-k}u(x) to obtain the code polynomial (Step 206);

b(x)+X^{n-k}u(x) Eq. 9.

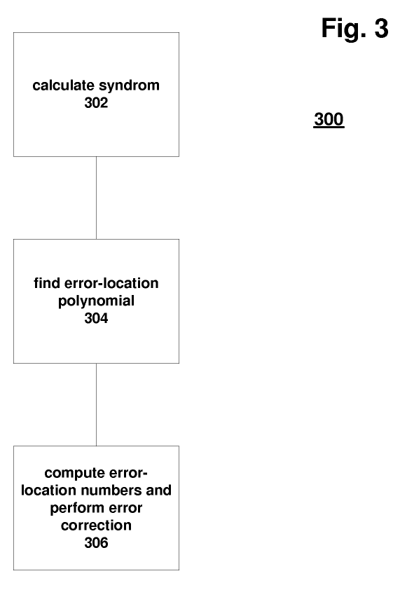

On the decoder side, in FIG. 3 a method 300 of decoding is shown. First, the syndrome of the code is calculated (Step 302).

Let Sᵢ=r(αⁱ)

S₁=r(α)=r₀+r₁α+r₂α²+ . . . +rₙ₋₁αⁿ⁻¹

S₂=r(α²)r₀+r₁α2+r₂α⁴+ . . . +rₙ₋₁(α²)n⁻¹Etc Equ. 10

generating syndrome values of the received BCH encoded signal, interpreting the syndrome values; and when the syndrome values do not equal zero, determining that the received BCH encoded signal includes errors.

Second, using Berlekamp's algorithm to find the error-location polynomial (Step 304).

| μ | σ^{(μ)}(x) | d μ | lμ | 2μ − lμ |
|---|---|---|---|---|
| ½ | 1 | 1 | 0 | −1 |
| 0 | 1 | S₁ | 0 | 0 |
| 1 | 1 + S₁X | S₃ + S₁ S₂ | 1 | 1 (ρ = −½) |
| 2 | 1 + S₁X + (S₃ + | S₅ + S₁ S₄ + (S₃/S₁ + S₂)S₃ | 2 | 2 (ρ = 0) |
| | S₁ S₂)X² | | | |
| 3 | σ⁽³⁾ | d3 | 3 | 3 (ρ = 1) |
| 4 | — | — | — | — |

σ⁽³⁾ (x) = 1 + S₁X + S₁X² + S₂X³
d₃ = S₇ + S₁S₆ + S₁S₅ + S₂S₄

σ⁽³⁾(x)=1+S₁X+S₁X²+S₂X³

d₃=S₇+S₁S₆+S₁S₅+S₂S₄

Where:

α₁=S₁α¹⁹⁹⁹

σ₂=(S₁+d₃d₂⁻¹)α^{1999×2}

σ₃=(S₁+d₃d₂⁻¹S₁)α^{1999×3}

σ⁴=d₃d₂⁻¹(S₃S₁⁻¹+S₂)α1999×4

Third, error location numbers is calculated and error correction is performed (Step 306) using Chien's search to compute error-location numbers and perform error correction. σσᵢ+σᵢ+αᵢα(σᵢ+σᵢ)

Let α¹²=1+α+α⁴+α⁶ then,

σα=(σ₀+σ₁α+σ₂α²+σ₃α³+σ₄α⁴+σ₅α⁵+σ₆α⁶+σ⁷α₇+σ₈α⁸+σ₉α⁹+σ₁₀α¹⁰+σ₁₁α¹¹)α Equ. 11

Equ. 11 can be reorganized as follows:

σα=σ₁₁+(σ₀+σ₁₁)α+σᵢα²+σᵢα³+(σᵢ+σᵢ)α⁴+σᵢα⁵+(σᵢ+σᵢ)α⁶+σᵢα⁷+σᵢα⁸+σᵢα⁹+σᵢα¹⁰+σᵢα¹¹ Equ. 12

Similarly, we have:

σα²=σᵢ+(σᵢ+σᵢ)α+(σᵢ+σᵢ)α²+σᵢα³+(σᵢ+σᵢ)α₄+(σᵢ+σᵢ)α⁵+(σᵢ+σᵢ)α⁶+(σᵢ+σᵢ)α⁷+σᵢα⁸+θᵢα⁹+σᵢα¹⁰+σᵢα¹¹ Equ. 13

σα³=σᵢ+(σᵢ+σᵢ)α+(σᵢ+σᵢ)α²+(σᵢ+σᵢ)α³+(σᵢ+σᵢ)α⁴+(σᵢ+σᵢ)α⁵+(σᵢ+σᵢ)α⁶+(σᵢ+σᵢ)α⁷+(σᵢ+σᵢ)α⁸+σᵢα⁹+σᵢα¹⁰+σᵢα¹ Equ. 14

σα⁴=σᵢ+(σᵢ+σᵢ)α+(σᵢ+σᵢ)α²+(σᵢ+σᵢ)α³+(σᵢ+σᵢ)α⁴+(σᵢ+σᵢ)α⁵+(σᵢ+σᵢ+σᵢ)α⁶+(σᵢ+σᵢ)α⁷+(σᵢ+σᵢ)α⁸+σᵢα⁹+σᵢα¹⁰+σᵢα¹ Equ. 15

let σ(x)=1+σ₀+σ₁x+σ₂x²+σ₃x³+σ₄x⁴ then

σ(α)=1+σ₀+σ₁α+σ₂α²+σ₃α³+σ₄α⁴

σ(α²)=1+σ₀+σ₂α²+σ₂α⁴+σ₃α⁶+σ₄α⁸

σ(α¹)=1+σ₀+σ₂α¹+σ₂α²+σ₃α³+σ₄α⁴¹

If the sum of the above is zero, then αⁿ⁻¹ is an error-location number.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A method for coding a BCH code comprising the steps of:
pre-multiplying a message u(x) by X^{n-k}; and
obtaining a remainder b(x).

2. The method of claim 1 further comprising the step of combining b(x) and X^{n-k}u(x) to obtain a code polynomial: b(x)+X^{n-k}u(x).

3. The method of claim 1, wherein the remainder b(x) comprises a set of parity check digits.

4. The method of claim 1, wherein the BCH code comprises 256 information bytes.

5. The method of claim 1, the BCH code comprises at most 8 bytes of parity check elements.

6. A method for de-coding a BCH code comprising the steps of:
calculating a syndrome of the BCH code;
finding an error-location polynomial; and
computing a set of error location numbers associated with the error-location polynomial.

7. The method of claim 6 further comprising the step of performing error correction.

8. The method of claim 6, wherein the BCH code comprises 256 information bytes.

9. The method of claim 6, the BCH code comprises at most 8 bytes of parity check elements.
